(19) United States
(12) Patent Application Publication
(10) Pub. No.: US 2009/0153226 A1
(43) Pub. Date: Jun. 18, 2009

(54) HIGH-SIDE DRIVER FOR PROVIDING AN OFF-STATE IN CASE OF GROUND LOSS

(75) Inventors: Bernhard Wicht, Munich (DE); Michael Wendt, Wasserburg (DE)

Correspondence Address: TEXAS INSTRUMENTS INCORPORATED, P O BOX 655474, M/S 3999, DALLAS, TX, 75265, US

(73) Assignee: TEXAS INSTRUMENTS DEUTSCHLAND GMBH, Freising (DE)

(21) Appl. No.: 12/253,002

(22) Filed: Oct. 16, 2008

Related U.S. Application Data
(60) Provisional application No. 61/017,011, filed on Dec. 27, 2007.

(30) Foreign Application Priority Data
Oct. 16, 2007 (DE) 1020070494876

(51) Int. Cl. H03K 17/687

(52) U.S. Cl. 327/427

(57) ABSTRACT

An electronic device has circuitry for driving a high side switch. The circuitry has a high side driver including a first switch and a second switch being coupled to each other by a driver output node. The driver output node is adapted to be coupled to a control input of the high side switch. The first switch is coupled to a driver high voltage level and the second switch is coupled to ground for alternately pulling the driver output node to either the driver high voltage level or to ground so as to turn the high side switch on and off. A diode element is coupled between the driver output node and the second switch in a forward direction from the driver output node to the switch.

### CROSS REFERENCE TO RELATED APPLICATIONS

This application claims the benefit of U.S. application Ser. No. 61/017,011 filed Dec. 27, 2007, which is incorporated herein in its entirety by reference.

### FIELD OF THE INVENTION

The present invention generally relates to a high-side driver circuit. More particularly, the present invention relates to a high-side driver that provides an off-state in the event of a ground loss.

### BACKGROUND OF THE INVENTION

High-side drivers find widespread application in all kinds of applications where they are generally used for driving a high side switch, usually implemented as a MOS transistor. The high side switch serves, for example, to switch a supply voltage to a load, and they are capable of delivering high peak currents of up to several amperes. Operation of high-side drivers is allowed with high supply voltages up to several tenths of Volts.

FIG. 1 shows a conventional high side driver HSDR as part of an electronic device for driving a high side switch MOS transistor HSSW. The high side switch HSSW is configured to connect a supply voltage VBAT, for example from a car battery, to a load, for example an indicator lamp or other automotive component, represented here by the resistor Rload. The high side driver HSDR is formed of two switches S1 and S2 coupled to each other in series. The point where the two switches S1 and S2 are coupled to each other forms a driver output node N1, which is coupled to the gate terminal of the MOS transistor forming the high side switch HSSW. The first switch S1 is coupled to a driver high voltage level VCP, which can be a charge pump voltage, and the second switch S2 is coupled to ground. The high side driver HSDR also comprises a pull-up circuit formed of a current source I1 and a resistor R connected in series between the driver high voltage level VCP and ground. In operation, when the switch S1 is turned on (conducting) the driver output node N1 is pulled to the driver high voltage level VCP. The gate of the MOS transistor forming the high side switch HSSW is then pulled to the driver high voltage level VCP and the MOS transistor high side switch HSSW turns on (is conducting) and switches on the load Rload; i.e., the load Rload is supplied with the supply voltage VBAT. When the switch S2 is turned on (conducting) the driver output node N1 is pulled to ground, thus the gate of the MOS transistor high side switch HSSW is also pulled to ground and the load Rload is switched off.

However, if a bond wire were to be broken, or there should be a defective chassis connection in an automotive application, this can result in a loss of ground to the high side driver HSDR. A ground loss can cause the switches S1 and/or S2 to turn on, which would cause the driver output node N1 to go high and activate the load Rload (for example a solenoid, relay or warning lamp in a car) unintentionally by switching the high side switch HSSW on. A potential current path during ground-loss could be from VCP through I1, R and S2 to node N1 as illustrated by the dashed line in FIG. 1. This could have serious safety implications in an automotive application and possibly lead to accidents and injuries. Furthermore, unintentional switching on of the switches S1 and S2, and therefore the load can cause damage to the integrated circuit associated with the high side driver, as well as to external loads and circuitry.

### SUMMARY OF THE INVENTION

The present invention provides an electronic device having circuitry for driving a high side switch MOS transistor. The circuitry comprises a high side driver including a first switch and a second switch being coupled to each other by a driver output node. The driver output node is adapted to be coupled to a control input of the high side switch (e.g. the gate of a high side switch MOS transistor). The first switch is coupled to a driver high voltage level and the second switch is coupled to ground for alternately pulling the driver output node to either the driver high voltage level or to ground so as to turn the high side switch on and off. Further, a diode element is coupled between the driver output node and the second switch in a forward direction from the driver output node to the switch. A high side driver has a driver output node formed at a point where a first switch and a second switch are coupled to each other, which provides a voltage for driving the high side switch MOS transistor. The driver output node is switched to a driver high voltage level when the first switch is turned on (conducting) and it is connected to ground when the second switch is turned on (conducting), since the first switch is coupled to the driver high voltage level and the second switch is coupled to ground. This means that the driver output node is alternately pulled to either the driver high voltage level or to ground, which alternately turns the high side switch on and off (the high side switch is conducting when the driver output node is at the driver high voltage level and is non-conducting when the driver output node is at ground). Between the driver output node and the second switch, a diode element is coupled so that it is forward biased in a direction from the driver output node to the switch. If there is a ground loss and the ground (e.g. substrate) potential is pulled up, the diode element then blocks any current flow through the second switch towards the driver output node and the high side switch will remain switched off (non conducting). Therefore, the present invention provides that any load that is normally switched by the high side switch will be prevented from being accidentally switched on in the case of a ground loss.

The high side switch can be a MOS transistor and a first resistor is coupled between the gate and a source of the high side MOS transistor. A first resistor is coupled to the gate terminal and the source terminal of the high side MOS transistor so that, in the event of a ground loss, the gate terminal of the high side MOS transistor is discharged through the first resistor to the same potential as its source terminal, thereby safely turning off the high side MOS transistor. This aspect is particularly advantageous if MOS transistors are used as high side switches, due to the high impedance of the gates. Since practically no current can flow through the gate, even small currents from the output node to the gate can cause failure of the high side switch. Therefore, a resistor coupled between gate and source can help to prevent unintentional switching and provide additional safety.

In one aspect of the invention, the first switch is a PMOS transistor and the second switch is a NMOS transistor. The PMOS transistor and the NMOS transistor have gates coupled to each other. A second resistor can then be coupled between the coupled gates and the driver high voltage level for providing a fail-safe pull-up driver. The first and second switches can be implemented as a PMOS transistor and an NMOS transistor, respectively, thereby forming a complementary CMOS pair. Gate terminals of the PMOS and NMOS transistor can then be coupled to each other. Between the point where the gate terminals are coupled and the driver high voltage level, a second resistor can be coupled. In the case of ground loss, the gate of the PMOS transistor can then be pulled high through the second resistor. The diode D prevents an alternative path through MN1, I1 and R2, that could connect node N1 to VCP. Since both pull-up paths through the PMOS transistor MP0 and through the NMOS transistor MN1 are disabled, the high side driver gets forced into a high output impedance. Hence the high side switch MOS transistor will not be switched on.

### BRIEF DESCRIPTION OF THE DRAWINGS

Further advantages and characteristics of the invention ensue from the description below of a preferred embodiment, and from the accompanying drawings, in which:

FIG. 1 is a simplified circuit diagram of a conventional electronic device having a high side driver for driving a high side switch MOS transistor; and

FIG. 2 is a simplified circuit diagram of an electronic device having a high side driver for driving a high side switch MOS transistor according to the invention.

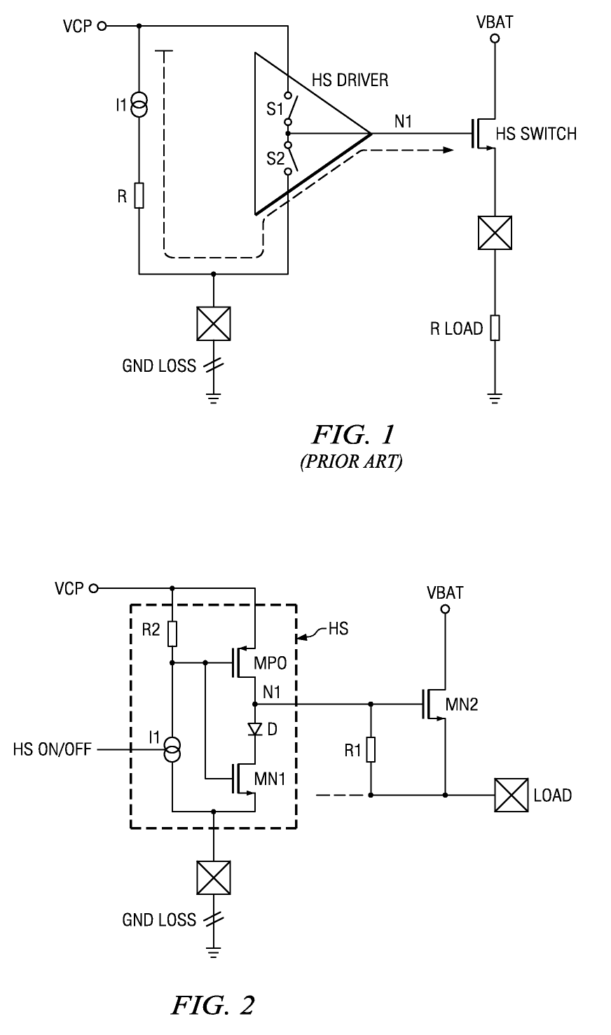

### DETAILED DESCRIPTION OF THE INVENTION

FIG. 2 shows an electronic device according to the invention having a high side driver HS. The high side driver HS has a first switch implemented as a PMOS transistor MP0 with a drain terminal coupled via a diode element D to the drain terminal of a second switch implemented as an NMOS transistor MN1. The source terminal of the first switch MP0 is connected to a driver high voltage level VCP, which can be a charge pump voltage, and the source terminal of the second switch MN1 is connected to ground. Gate terminals of the two switches MP0 and MN1 are coupled to each other. A resistor R2 is connected between the coupled gate terminals of the switches MP0 and MN1 and the driver high voltage level and a current source I1, which is controlled by any suitable control circuitry, is connected between the resistor R2 and ground and is operable to switch the high side driver HS on and off by turning the switches MP0 and MN1 on and off.

The diode element D is forward biased in a direction from the PMOS transistor MP0 to the NMOS transistor MN1. A driver output node N1 is provided between the drain of the transistor MP0 and the diode D and is connected to the gate terminal of a MOS transistor high side switch implemented as a NMOS transistor MN1. The source terminal of the transistor high side switch MN2 is connected to a load LOAD, for example an automotive component such as an indicator lamp, and the drain terminal of the transistor high side switch MN2 is connected to a supply voltage VBAT, for example a battery. A resistor R1 is coupled to both, the gate and the source terminals of the transistor high side switch MN2. The transistor high side switch MN2 is usually provided on a different integrated circuit to the high side driver HS, however both the high side driver HS and the high side switch MN2 may also be provided on the same chip or integrated circuit.

For switching on the load LOAD, the current source I1 is switched off so that the gate voltages of the switches MP0 and MN1 are low. This means that the switch MP0 is turned on (conducting) and the switch MN1 is turned off so that the node N1, and therefore the gate of the transistor high side switch MN2, is pulled to the high driver voltage VCP. The transistor high side switch MN2 is then turned on (conducting) and the load LOAD is connected to the supply voltage VBAT. In order to disconnect the load LOAD from the supply voltage VBAT so as to switch it off, the current source I2 is switched on so that the gate voltages of the switches MP0 and MN1 are low. The switch MP0 is then turned off (non-conducting) and the switch MN1 is turned on so that the node N1 is disconnected from the high driver voltage VCP and is instead pulled to ground. Therefore the gate voltage of the transistor high side switch MN2 is also pulled to ground and the transistor high side switch MN2 becomes non-conducting. This means that the load LOAD is then disconnected from the supply voltage VBAT.

If a ground loss occurs, in the event of a defective chassis connection, for example, the gate terminal of the switch MP0 is pulled high through the resistor R2. This forces the driver output node N1 to a high impedance. Hence the resistor R1 discharges the gate of the transistor high side switch MN2 to the same potential as its source terminal, which stops the high side switch MN2 from conducting so that the load is disconnected from the supply voltage VBAT and is safely switched off. If the ground; i.e., the substrate potential, is pulled high in the event of a ground loss, the diode element D blocks any current flow through the switch MN1 (i.e., through the parasitic junction of MN1) towards the node N0, and thus the gate of the transistor high side switch MN2, so that the switch MN2 will not be turned on and the load LOAD will remain switched off.

Although the present invention has been described with reference to a specific embodiment, it is not limited to this embodiment and no doubt further alternatives will occur to the skilled person that lie within the scope of the invention as claimed. For example, the resistor R2 and current source I1 can be replaced with any other suitable pull-up circuitry.

1. An electronic device having circuitry for driving a high side switch (MN2), the circuitry comprising:
a high side driver (HS) including a first switch (MP0) and a second switch (MN1) being coupled to each other by a driver output node (N1) adapted to be coupled to a control input of the high side switch (MN2);
the first switch (MP0) being coupled to a driver high voltage level (VCP) and the second switch (MN1) being coupled to ground for alternately pulling the driver output node (N1) to either the driver high voltage level (VCP) or to ground so as to turn the high side switch (MN2) on and off, wherein
a diode element (D) is coupled between the driver output node (N1) and the second switch (MN1) in a forward direction from the driver output node (N1) to the switch (MN1).

2. The electronic device according to claim 1, wherein the high side switch is a MOS transistor and further comprising a first resistor (R1) coupled between the gate and a source of the high side MOS transistor.

3. The electronic device according to claim 1, wherein the first switch (MP0) is a PMOS transistor and the second switch (MN1) is a NMOS transistor, the PMOS transistor and the NMOS transistor having gates coupled to each other and wherein a second resistor (R1) is coupled between the coupled gates and the driver high voltage level (VCP) for providing a fail-safe pull-up driver.

4. The electronic device according to claim 2, wherein the first switch (MP0) is a PMOS transistor and the second switch (MN1) is a NMOS transistor, the PMOS transistor and the NMOS transistor having gates coupled to each other and wherein a second resistor (R1) is coupled between the coupled gates and the driver high voltage level (VCP) for providing a fail-safe pull-up driver.
